(19) United States
(12) Patent Application Publication
(10) Pub. No.: US 2018/0166447 A1
(43) Pub. Date: Jun. 14, 2018

(54) SEMICONDUCTOR DEVICE

(71) Applicant: Samsung Electronics Co., Ltd., Suwon-Si (KR)

(72) Inventors: Ji Ung Pak, Suwon-Si (KR); Won Chul Lee, Seongnam-Si (KR); Je Min Park, Suwon-Si (KR)

(21) Appl. No.: 15/677,726

(22) Filed: Aug. 15, 2017

(30) Foreign Application Priority Data
Dec. 9, 2016 (KR) 10-2016-0167214

(51) Int. Cl. H01L 27/108; H01L 49/02

(52) U.S. Cl. CPC H01L 27/10808; H01L 27/10852; H01L 28/91

(57) ABSTRACT

A semiconductor device includes a substrate, first, second and third structures disposed on the substrate and spaced apart from one another in a first direction, wherein each of the first, second and third structures includes lower electrodes, and a supporter pattern supporting the first, second and third structures and including a first region and a second region, wherein the first region exposes first parts of sidewalls of the first, second and third structures, and the second region surrounds second parts of the sidewalls of the first, second and third structures. A first length of a sidewall of the supporter pattern between the first and second structures is greater than a first distance between the first and second structures. A second length of a sidewall of the supporter pattern between the second and third structures is greater than a second distance between the second and third structures.

### CROSS-REFERENCE TO RELATED APPLICATION

This application claims priority under 35 U.S.C. § 119 to Korean Patent Application No. 10-2016-0167214 filed on Dec. 9, 2016, the disclosure of which is incorporated by reference herein in its entirety.

### TECHNICAL FIELD

The present inventive concept relates to a semiconductor device.

### DISCUSSION OF THE RELATED ART

As the integration density of memory devices has increased in due to rapid developments in semiconductor technology, the area of unit cells has decreased, and the operating voltage of semiconductor devices has been lowered. For example, as the integration density of a semiconductor device such as a dynamic random access memory (DRAM) increases, the area occupied by the semiconductor device decreases, but the capacitance of the semiconductor device may be maintained or increased. As the capacitance of the semiconductor device increases, the aspect ratio of cylindrical lower electrodes increases. However, this may cause the cylindrical lower electrodes to collapse or break before dielectric deposition.

### SUMMARY

According to an exemplary embodiment of the present inventive concept, a semiconductor device includes a substrate, first, second and third structures disposed on the substrate and spaced apart from one another in a first direction, wherein each of the first, second and third structures includes lower electrodes, and a supporter pattern supporting the first, second and third structures and including a first region and a second region, wherein the first region exposes first parts of sidewalls of the first, second and third structures, and the second region surrounds second parts of the sidewalls of the first, second and third structures. A first length of a sidewall of the supporter pattern between the first and second structures is greater than a first distance between the first and second structures. A second length of a sidewall of the supporter pattern between the second and third structures is greater than a second distance between the second and third structures.

According to an exemplary embodiment of the present inventive concept, A semiconductor device includes a substrate, a first structure disposed on the substrate and including a first lower electrode, a second structure disposed on the substrate and including a second lower electrode, wherein the second structure is spaced apart from the first structure in a first direction, a third structure disposed on the substrate and including a third lower electrode, wherein the third structure is spaced apart from the first structure in a second direction that crosses the first direction, and a supporter pattern supporting the first, second and third structures and including a first region and a second region. The first region exposes first parts of sidewalls of the first, second and third structures, and the second region surrounds second parts of the sidewalls of the first, second and third structures. A center of each of the first, second and third structures is a point on a circle that intersects each of the first, second and third structures. A first length of a sidewall of the supporter pattern between the first and second structures is greater than a second length of a part of the circle between the first and second structures.

According to an exemplary embodiment of the present inventive concept, a semiconductor device including a substrate, first, second and third structures disposed on the substrate and spaced apart from one another in a first direction, wherein each of the first, second and third structures includes lower electrodes. The semiconductor device further includes fourth, fifth and sixth structures respectively spaced apart from the first, second and third structures in a second direction crossing the first direction, wherein each of the fourth, fifth and sixth structures includes lower electrodes, and a supporter pattern supporting the first, second, third, fourth, fifth and sixth structures and including a first region and a second region. The first region exposes first parts of sidewalls of the first, second, third, fourth, fifth and sixth structures, and the second region surrounds second parts of the sidewalls of the first, second, third, fourth, fifth and sixth structures. A first length of a sidewall of the supporter pattern between the first and second structures is greater than a first distance between the first and second structures, and a second length of a sidewall of the supporter pattern between the first and fourth structures is greater than a second distance between the first and fourth structures.

### BRIEF DESCRIPTION OF THE DRAWINGS

The above and other features of the present inventive concept will become more apparent by describing in detail exemplary embodiments thereof, with reference to the accompanying drawings, in which:

FIG. 1 is a schematic view illustrating a semiconductor device according to an exemplary embodiment of the present inventive concept;

FIG. 2 is a cross-sectional view taken along line A-A′ of FIG. 1 according to an exemplary embodiment of the present inventive concept;

FIGS. 3, 4, 5, 6, 7, 8 and 9 are cross-sectional views illustrating a method of fabricating a semiconductor device according to an exemplary embodiment of the present inventive concept;

FIG. 10 is a cross-sectional view illustrating a semiconductor device according to an exemplary embodiment of the present inventive concept;

FIG. 11 is a schematic view illustrating a semiconductor device according to an exemplary embodiment of the present inventive concept;

FIG. 12 is a schematic view illustrating a semiconductor device according to an exemplary embodiment of the present inventive concept;

FIG. 13 is a schematic view illustrating a semiconductor device according to an exemplary embodiment of the present inventive concept;

FIG. 14 is a schematic view illustrating a semiconductor device according to an exemplary embodiment of the present inventive concept;

FIG. 15 is a schematic view illustrating a semiconductor device according to an exemplary embodiment of the present inventive concept;

FIG. 16 is a schematic view illustrating a semiconductor device according to an exemplary embodiment of the present inventive concept;

FIG. 17 is a schematic view illustrating a semiconductor device according to an exemplary embodiment of the present inventive concept; and

FIG. 18 is a schematic view illustrating a semiconductor device according to an exemplary embodiment of the present inventive concept.

### DETAILED DESCRIPTION OF THE EMBODIMENTS

Exemplary embodiments of the present inventive concept will be described more fully hereinafter with reference to the accompanying drawings.

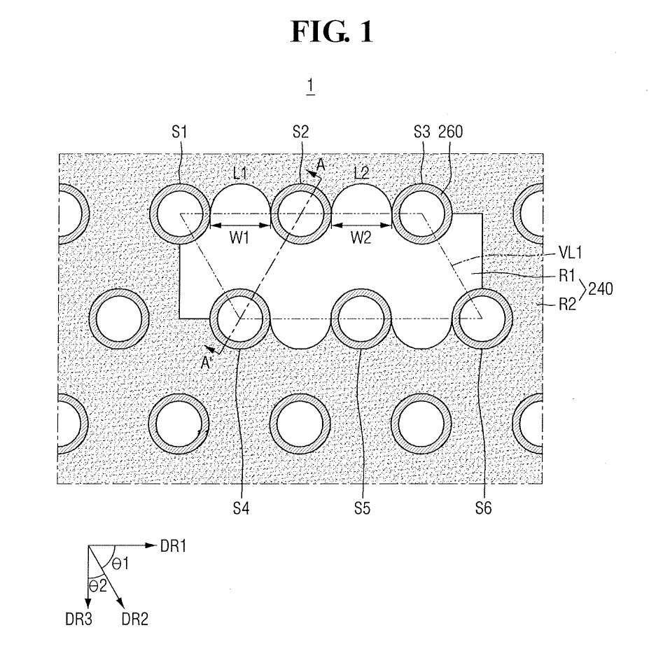

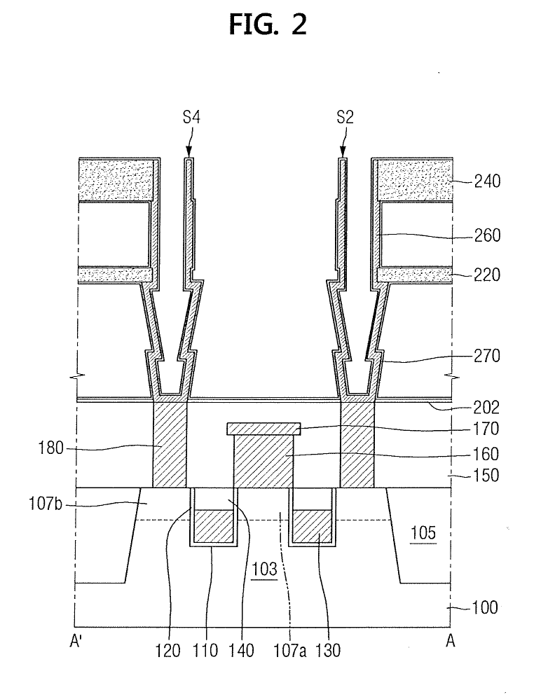

A semiconductor device according to an exemplary embodiment of the present inventive concept will hereinafter be described with reference to FIG. 1 and FIG. 2.

FIG. 1 is a schematic view illustrating a semiconductor device according to an exemplary embodiment of the present inventive concept. FIG. 2 is a cross-sectional view taken along line A-A′ of FIG. 1 according to an exemplary embodiment of the present inventive concept.

Referring to FIG. 1 and FIG. 2, a semiconductor device 1 includes a substrate 100, lower electrodes 260, a first supporter pattern 220, a second supporter pattern 240, and a capacitor dielectric film 270 (see, e.g., FIG. 2).

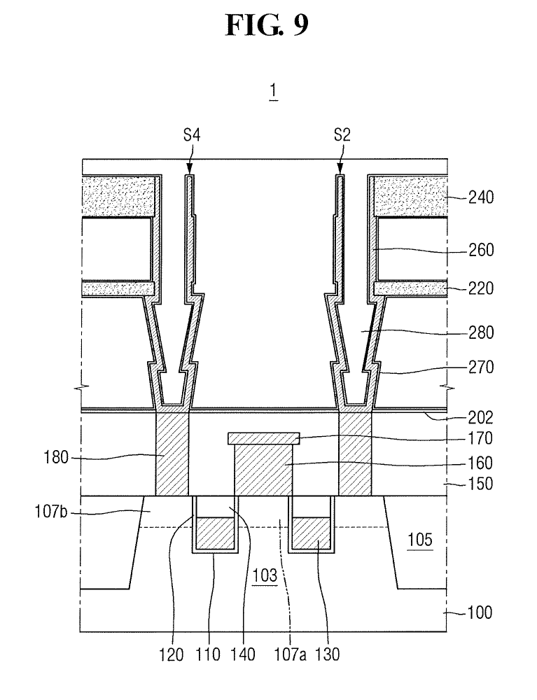

The semiconductor device 1 may include an upper electrode 280, which is disposed on the capacitor dielectric film 270, as illustrated in FIG. 9. This will be described later in detail.

Referring to FIG. 1, the semiconductor device 1 may include a plurality of structures that are spaced apart from one another. For example, first through third structures S1 through S3 may be spaced apart from one another in a first direction DR1, a fourth structure S4 may be spaced apart from the first structure S1 in a second direction DR2, a fifth structure S5 may be spaced apart from the second structure S2 in the second direction DR2, and a sixth structure S6 may be spaced apart from the third structure S3 in the second direction DR2.

The fourth through sixth structures S4 through S6 may be spaced apart from one another in the first direction DR1. For example, the first through third structures S1 through S3 are in a first row extending in the first direction DR1, and the fourth through sixth structures S4 through S6 are in a second row extending in the first direction DR1 and parallel to the first row. However, the present inventive concept is not limited thereto.

An angle θ1 that the first and second directions DR1 and DR2 form with each other may be an acute angle. For example, the angle θ1 may be about 60 degrees, but the present inventive concept is not limited thereto. For example, the angle θ1 may be an obtuse angle. In this example, each of the first through sixth structures S1 through S6 may be disposed at the center or one of the vertices of a hexagon that is a part of a honeycomb shape.

In an exemplary embodiment of the present inventive concept, first imaginary lines VL1 that sequentially connect the centers of the first through sixth structures S1 through S6 may form a parallelogrammatic shape, but the present inventive concept is not limited thereto. In other words, in an exemplary embodiment of the present inventive concept, the distance between the first and fourth structures S1 and S4 may differ from the distance between the second and fifth structures S2 and S5.

Each of the first through sixth structures S1 through S6 may include a lower electrode 260, which is formed along the sidewalls of its corresponding structure, a capacitor dielectric film 270 (see, e.g., FIG. 2), which is disposed on the lower electrode 260, and an upper electrode 280 (see, e.g., FIG. 9), which is disposed on the capacitor dielectric film 270. For convenience, the capacitor dielectric film 270 and the upper electrode 280 are not illustrated in FIG. 1.

The second supporter pattern 240 may include a first region R1, which exposes parts of the sidewalls of each of the first through sixth structures S1 through S6, and a second region R2, which surrounds other parts of the sidewalls of each of the first through sixth structures S1 through S6. Accordingly, the second supporter pattern 240 can support each of the first through sixth structures S1 through S6.

FIG. 1 illustrates the first region R1 of the second supporter pattern 240 as being formed only among the first through sixth structures S1 through S6, but the present inventive concept is not limited thereto. In other words, the first region R1 of the second supporter pattern 240 may be formed among other structures that are adjacent to one another.

Sidewalls of the second supporter pattern 240, which are between the first and second structures S1 and S2 and between the second and third structures S2 and S3, may have a convex shape protruded toward the second region R2 of the second supporter pattern 240, as illustrated in FIG. 1.

In addition, sidewalls of the second supporter pattern 240, which are between the fourth and fifth structures S4 and S5 and between the fifth and sixth structures S5 and S6, may have a convex shape protruded toward the second region R2, as illustrated in FIG. 1.

Accordingly, a first length L1 of the sidewall of the second supporter pattern 240 between the first and second structures S1 and S2 may be greater than a first distance W1 between the first and second structures S1 and S2. In addition, a second length L2 of the sidewall of the second supporter pattern 240 between the second and third structures S2 and S3 may be greater than a second distance W2 between the second and third structures S2 and S3.

In addition, the length of the sidewall of the second supporter pattern 240 between the fourth and fifth structures S4 and S5 may be greater than the distance between the fourth and fifth structures S4 and S5. In addition, the length of the sidewall of the second supporter pattern 240 between the fifth and sixth structures S5 and S6 may be greater than the distance between the fifth and sixth structures S5 and S6.

As a result, s-poly bridge disturb (SBD) margins can be secured among the lower electrodes 260 of the first through sixth structures S1 through S6 of, for example, a dynamic random access memory (DRAM). In other words, by providing the sidewalls of the second supporter pattern 240 with a curve (e.g., an arch shape) between the first through third structures S1 through S3 and between the fourth through sixth structures S4 through S6, bridges, which may be formed among the first through sixth structures S1 through S6, may be longer than the distance between the first through sixth structures S1 through S6. Thus, the integration density of the DRAM may be increased.

Referring to FIG. 2, in an exemplary embodiment of the present inventive concept, the substrate 100 may have a structure in which a base substrate and an epitaxial layer are stacked, but the present inventive concept is not limited thereto. In other words, in an exemplary embodiment of the present inventive concept, the substrate 100 may be any one of a silicon substrate, a gallium arsenide substrate, a silicon germanium substrate, a ceramic substrate, a quartz substrate, a glass substrate, and a semiconductor-on-insulator (SOI) substrate. Hereinafter, for example, the substrate 100 will be described as a silicon substrate. The substrate 100 may be of a first conductivity type (for example, a P type), but the present inventive concept is not limited thereto.

A bitline 170 and gate electrodes 130, which are used as wordlines, may be disposed between the substrate 100 and lower electrodes 260.

For example, a unit active region 103 and isolation regions 105 may be provided on the substrate 100. For example, two transistors may be disposed in the unit active region 103. However, the present inventive concept is not limited thereto.

The two transistors may include two gate electrodes 130, which are disposed in the unit active region 103, a first source/drain region 107a, which is formed in the unit active region 103 between the two gate electrodes 130, and second source/drain regions 107b, which are formed between the gate electrodes 130 and the isolation regions 105. In other words, the two transistors share the first source/drain region 107a, but do not share the second source/drain regions 107b.

A gate insulating film 120 may be disposed along sidewalls and bottoms of first trenches 110. The gate insulating film 120 may comprise, for example, silicon oxide or a high-k dielectric material with a higher dielectric constant than that of silicon oxide.

The gate electrodes 130 may be disposed in the first trenches 110. The gate electrodes 130 may partially fill the first trenches 110. In other words, the gate electrodes 130 may be recessed.

The gate electrodes 130 may include one of, for example, doped polysilicon, titanium nitride (TiN), tantalum nitride (TaN), tungsten nitride (WN), titanium (Ti), tantalum (Ta), and tungsten (W), but the present inventive concept is not limited thereto.

Capping patterns 140 may be disposed on the gate electrodes 130 to fill the first trenches 110. The capping patterns 140 may comprise an insulating material, for example, at least one of silicon oxide, silicon nitride, and silicon oxynitride.

An interlayer dielectric film 150 may be disposed on the substrate 100. The interlayer dielectric film 150 may comprise, for example, at least one of silicon oxide, silicon nitride, and silicon oxynitride. The interlayer dielectric film 150 may be disposed as a single layer or a multilayer.

A first contact plug 160 may be provided in the interlayer dielectric film 150 and may be electrically connected to the first source/drain region 107a. The first contact plug 160 may comprise a conductive material, for example, at least one of a polycrystalline silicon, a metal silicide compound, a conductive metal nitride, and a metal, but the present inventive concept is not limited thereto.

The bitline 170, which is electrically connected to the first contact plug 160, may be disposed on the first contact plug 160. The bitline 170 may comprise a conductive material, for example, at least one of a polycrystalline silicon, a metal silicide compound, a conductive metal nitride, and a metal, but the present inventive concept is not limited thereto.

Second contact plugs 180 may be provided to penetrate the interlayer dielectric film 150. The second contact plug 180 may be electrically connected to the second source/drain regions 107b. The second contact plugs 180 may include storage node contacts.

The second contact plugs 180 may comprise a conductive material, for example, at least one of a polycrystalline silicon, a metal silicide compound, a conductive metal nitride, and a metal, but the present inventive concept is not limited thereto.

The lower electrodes 260 may be disposed on the substrate 100. For example, the lower electrodes 260 may be disposed on the interlayer dielectric film 150, which covers the gate electrodes 130 and the bitline 170. The lower electrodes 260 may be electrically connected to the second contact plugs 180. The lower electrodes 260 may extend vertically from a surface of the substrate 100. In other words, the lower electrodes 260 may extend in a thickness direction of the substrate 100.

In an exemplary embodiment of the present inventive concept, the lower electrodes 260 may have a cylindrical shape. The sidewalls of the lower electrodes 260 may be stepped, but the present inventive concept is not limited thereto.

The lower electrodes 260 may comprise at least one of a doped polysilicon, a conductive metal nitride (for example, TiN, TaN, or WN), a metal (for example, ruthenium (Ru), iridium (Ir), Ti, or Ta), and a conductive metal oxide (for example, iridium oxide).

First and second supporter patterns 220 and 240 may be disposed between the lower electrodes 260 and their respective neighboring lower electrodes 260. As illustrated in FIG. 1 and FIG. 2, the first and second supporter patterns 220 and 240 might not be disposed between the first and fourth structures S1 and S4, between the second and fifth structures S2 and S5, and between the third and sixth structures S3 and S6.

The first and second supporter patterns 220 and 240 may be disposed on outer sidewalls of the lower electrodes 260, which face away from the first region R1, and may connect the lower electrodes 260 and their respective neighboring lower electrodes 260. The first and second supporter patterns 220 and 240 may be placed in contact with, for example, the lower electrodes 260.

The first and second supporter patterns 220 and 240 may be spaced apart from each other. For example, the first and second supporter patterns 220 and 240 may be spaced apart from each other in a direction in which the lower electrodes 260 extend. For example, the first supporter pattern 220 may be disposed closer than the second supporter pattern 240 to the top surface of the substrate 100.

The height of the lower electrodes 260 from the substrate 100 may be the same as the height of the second supporter pattern 240 from the substrate 100. For example, the top surface of the second supporter pattern 240 may be formed at the tops of the lower electrodes 260.

The first supporter pattern 220 may comprise, for example, at least one of silicon oxynitride, silicon nitride, silicon carbon nitride, and tantalum oxide. The second supporter pattern 240 may comprise, for example, silicon nitride, but the present inventive concept is not limited thereto.

The capacitor dielectric film 270 may be conformally formed on the lower electrodes 260 and the first and second supporter patterns 220 and 240. The capacitor dielectric film 270 may be formed on the outer and inner sidewalls of the lower electrodes 260. For example, the capacitor dielectric film 270 may be formed on the entirety of the outer and inner sidewalls of the lower electrodes 260. The capacitor dielectric film 270 may include a single layer or a multilayer.

The capacitor dielectric film 270 may comprise at least one of silicon oxide, silicon nitride, silicon oxynitride, and a high-k material. Examples of the high-k material include, but are not limited to, at least one of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

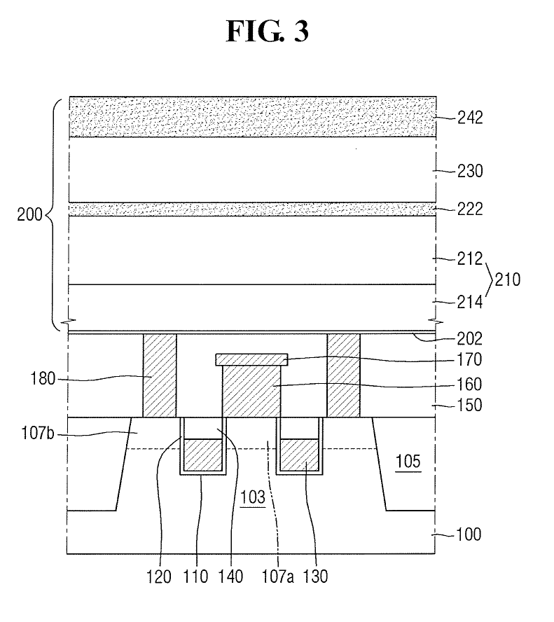

A method of fabricating a semiconductor device according to an exemplary embodiment of the present inventive concept will hereinafter be described with reference to FIG. 3 through FIG. 9.

FIG. 3 through FIG. 9 are cross-sectional views illustrating a method of fabricating a semiconductor device according to an exemplary embodiment of the present inventive concept.

Referring to FIG. 3, an insulating layer 200 is formed on a substrate 100. The insulating layer 200 may include a first mold film 210, a first supporter film 222, a second mold film 230, and a second supporter film 242, which are sequentially stacked.

For example, an etching stopper film 202 is formed on an interlayer dielectric film 150 on which a first contact plug 160 and second contact plugs 180 are formed. The first mold film 210, the first supporter film 222, the second mold film 230, and the second supporter film 242 may be sequentially formed on the etching stopper film 202.

The etching stopper film 202 may comprise a material having an etching selectivity with respect to the first and second mold films 210 and 230, which comprise an oxide. The etching stopper film 202 may be formed on the interlayer dielectric film 150 using a chemical vapor deposition (CVD) method. The etching stopper film 202 may comprise, for example, silicon nitride, but the present inventive concept is not limited thereto.

The first mold film 210 may be formed on the etching stopper film 202. The first mold film 210 may comprise silicon oxide. For example, the first mold film 210 may comprise flowable oxide (FOX), tonen silazen (TOSZ), undoped silica glass (USG), borosilicate glass (BSG), phosphosilicate glass (PSG), borophosphosilicate glass (BPSG), plasma enhanced tetra ethyl ortho silicate (PE-TEOS), fluoride silicate glass (FSG), a high density plasma (HDP) oxide, plasma enhanced oxide (PEOX), a flowable CVD (FCVD) oxide, or a combination thereof.

The first mold film 210 may include a first upper mold film 212 and a first lower mold film 214, which have different etching speeds from each other. For example, the first lower mold film 214 may comprise an oxide doped with impurities, and the first upper mold film 212 may comprise an oxide not doped with impurities.

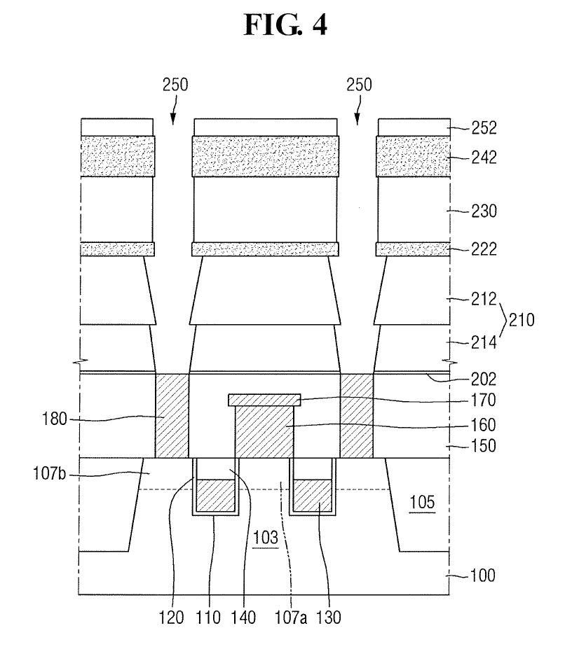

The first lower mold film 214 may comprise BPSG or PSG, and the first upper mold film 212 may comprise PE-TEOS or an HDP-CVD oxide. During a subsequent etching process, the first lower mold film 214 may be etched at a higher speed than the first upper mold film 212. Due to the difference between the speed at which the first lower mold film 214 is etched and the speed at which the first upper mold film 212 is etched, stepped shapes or pyramid shapes may be formed on the sidewalls of contact holes 250 of FIG. 4.

The first supporter film 222 may be formed on the first mold film 210. The first supporter film 222 may be transformed into the first supporter pattern 220 of FIG. 2 by being subjected to a subsequent process discussed later. The location of the first supporter film 222 may be adjusted based on the shape of the contact holes 250 of FIG. 4, which are to be formed later, and any change in the etching time for forming the contact holes 250 of FIG. 4 because of layers with different etching speeds.

The first supporter film 222 may comprise a material having an etching selectivity with respect to the first and second mold films 210 and 230. In a case in which the first and second mold films 210 and 230 comprise an oxide, the first supporter film 222 may comprise, for example, at least one of silicon oxynitride, silicon nitride, silicon carbon nitride, and tantalum oxide.

The second mold film 230 may be formed on the first supporter film 222. The second mold film 230 may comprise at least one of the aforementioned oxides that may be included in the first mold film 210. The second mold film 230 may comprise, for example, PE-TEOS or an HDP-CVD oxide.

The second mold film 230 may be formed using an oxide having a different concentration of impurities from the oxide used to form the first mold film 210. As a result, the first and second mold films 210 and 230 may be etched at different speeds from each other.

The second supporter film 242 may be formed on the second mold film 230. The second supporter film 242 may be transformed into the second supporter pattern 240 of FIG. 2 by being subjected to a subsequent process.

The second supporter film 242 may comprise a material having an etching selectivity with respect to the first and second mold films 210 and 230. In a case in which the first and second mold films 210 and 230 comprise an oxide, the second supporter film 242 may comprise, for example, at least one of silicon oxynitride, silicon nitride, silicon carbon nitride, and tantalum oxide.

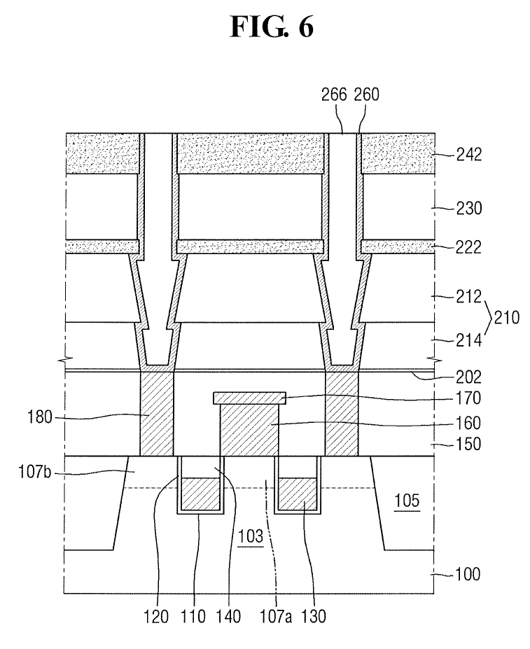

Thereafter, referring to FIG. 4, a node mask 252 may be formed on the second supporter film 242. For example, a mask layer, which comprises a material having an etching selectivity with respect to the second supporter film 242, may be formed on the insulating layer 200. By etching the mask layer, the node mask 252, which defines areas in which to form the contact holes 250 to form the lower electrodes 260 of FIG. 6, may be formed on the second supporter film 242.

Thereafter, the contact holes 250 may be formed in the insulating layer 200. The contact holes 250 may be formed by etching the insulating layer 200 using the node mask 252 as an etching mask. In other words, the contact holes 250 may be formed in the insulating layer 200 by etching the second supporter film 242, the second mold film 230, the first supporter film 222, the first mold film 210, and the etching stopper film 202. The second contact plugs 180 may be exposed by the contact holes 250.

An etching step for forming the contact holes 250 may involve, for example, performing at least one of wet etching and dry etching. For example, the second supporter film 242, which comprises silicon nitride, may be etched using an etching gas for etching a nitride. Thereafter, the second mold film 230, the first supporter film 222, the first mold film 210, and the etching stopper film 202 may be etched by separate etching processes. In a case in which the contact holes 250 are formed by multiple etching processes, uniformity of the etching step for forming the contact holes 250 may be increased.

After the etching step for forming the contact holes 250, a rinsing process may be performed. As a result of the rinsing process, any byproducts such as a native oxide layer or a polymer may be removed from the substrate 100 where the contact holes 250 are formed.

In a case in which the rinsing process is performed using a rinsing liquid comprising deionized water and an aqueous ammonia solution (or sulfuric acid), the first and second mold films 210 and 230 may be partly etched so that the diameter of the contact holes 250 may be enlarged. In addition, the first and second supporter films 222 and 242, which comprise a material having an etching selectivity with respect to the first and second mold films 210 and 230, may not be rinsed off during the rinsing process.

As a result, the first and second supporter films 222 and 242 might not be coplanar with a side surface of the first mold film 210 and a side surface of the second mold film 230 in each contact hole 250. In other words, they may partly extend in each contact hole 250. Thus, the first and second supporter films 222 and 242 may be projected (e.g., protruded) into the contact holes 250.

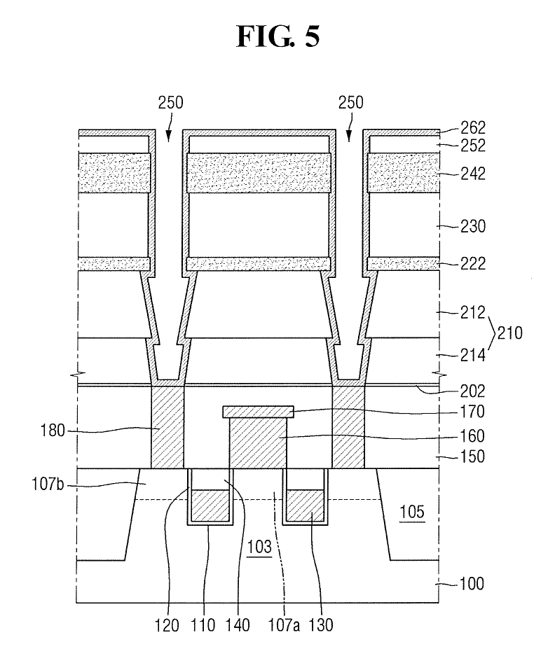

Thereafter, referring to FIG. 5, a lower electrode film 262 may be formed on the top surfaces of the second contact plugs 180, the sidewalls of the contact holes 250, parts of the first and second supporter films 222 and 242 that are projected, and the node mask 252.

The lower electrode film 262 may comprise a conductive material, for example, at least one of doped polysilicon, a conductive metal nitride (for example, TiN, TaN, or WN), a metal (for example, Ru, Ir, Ti, or Ta), and a conductive metal oxide (for example, iridium oxide).

Since parts of the first and second supporter films 222 and 242 are projected to horizontally inside the contact holes 250, the lower electrode film 262 may be formed to surround the projected parts of the first and second supporter films 222 and 242. For example, the lower electrode film 262 may cover the projected parts of the first and second supporter films 222 and 242.

Thereafter, referring to FIG. 6, a sacrificial film 266 may be formed on the lower electrode film 262 and may fill the contact holes 250. The sacrificial film 266 may comprise a material with gap filling properties, for example, an oxide such as USG or spin-on-glass (SOG). The sacrificial film 266 may protect parts of the lower electrode film 262 inside the contact holes 250 during polishing and etching processes for completing the formation of the lower electrodes 260.

Thereafter, the node mask 252, parts of the lower electrode film 262 outside of the contact holes 250 and the sacrificial film 266 may be removed by performing at least one of a chemical mechanical polishing (CMP) process and an etch-back process until the second supporter film 242 is exposed.

Thus, the lower electrodes 260, which are electrically connected to the second contact plugs 180, may be formed in the contact holes 250. The lower electrodes 260 may be electrically isolated from each other. The sacrificial film 266 may fill the contact holes 250 where the lower electrodes 260 are formed.

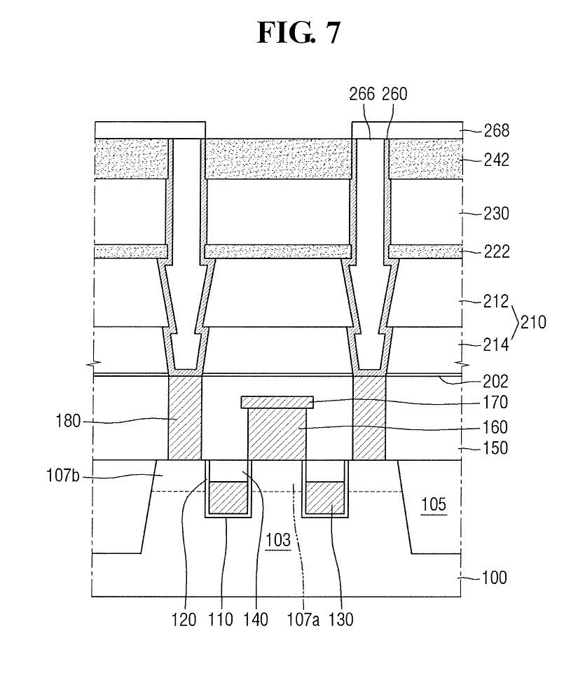

Thereafter, referring to FIG. 7, a mask pattern 268 may be formed on parts of the second supporter film 242, the lower electrodes 260, and the sacrificial film 266.

For example, the mask pattern 268 may be formed on the lower electrodes 260, the sacrificial film 266, and the entire second supporter film 242 except for a part of the second supporter film 242 in what will become the first region R1 of the second supporter pattern 240 of FIG. 1.

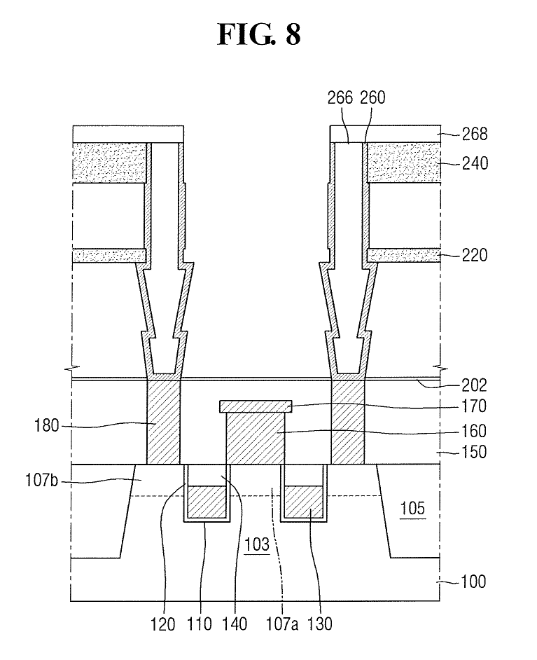

Thereafter, referring to FIG. 8, first and second supporter patterns 220 and 240 may be formed by etching the insulating layer 200 using the mask pattern 268 as a mask.

For example, parts of the sidewalls of the lower electrodes 260 may be exposed by etching away the second mold film 230 and parts of the second supporter film 242, the first supporter film 222, and the first mold film 210 between the lower electrodes 260 by using the mask pattern 268 as a mask.

The part of the second supporter film 242 between the lower electrodes 260 may be removed by an etching process, for example, a dry etching process. As a result, the second supporter pattern 240 may be formed.

Thereafter, the second mold film 230 between the lower electrodes 260 may be removed by performing an etching process, for example, a wet etching process, using a trench obtained by removing the second supporter film 242. The second mold film 230 may also be removed from below the mask pattern 268.

Thereafter, the part of the first supporter film 222 between the lower electrodes 260 may be removed by performing an etching process, for example, a dry etching process. As a result, the first supporter pattern 220 may be formed.

Thereafter, the first mold film 210 between the lower electrodes 260 may be removed by performing an etching process, for example, a wet etching process, using a trench obtained by removing the first supporter film 222. The first mold film 210 may also be removed from below the mask pattern 268.

As described above, parts of the first and second supporter films 222 and 242 may be removed by a dry etching process, but the present inventive concept is not limited thereto. As described above, the first and second mold films 210 and 230 may be removed by a wet etching process, but the present inventive concept is not limited thereto.

In the semiconductor device 1, the first region R1 of the second supporter pattern 240 of FIG. 1, e.g., an open region, may be formed by changing the mask pattern 268. In semiconductor devices according to exemplary embodiments of the present inventive concept, which will be described later, an open region, like the first region R1 of the second supporter pattern 240, may also be formed by changing a mask pattern.

Thereafter, referring to FIG. 9, a capacitor dielectric film 270 may be conformally formed on the outer sidewalls and the inner sidewalls of the lower electrodes 260, the first and second supporter patterns 220 and 240, and the etching stopper film 202 after the removal of the mask pattern 268 and the sacrificial film 266. Thus, the cross-sectional structure illustrated in FIG. 2 may be formed.

Thereafter, an upper electrode 280 may be formed on the capacitor dielectric film 270. For example, the upper electrode 280 may be formed between the lower electrodes 260 and in cylindrical structures of what were once contact holes 250 (see, e.g., FIG. 4), respectively. In addition, the upper electrode 280 may be formed between the lower electrodes 260 and their respective neighboring lower electrodes 260, between the first and second supporter patterns 220 and 240, and between the first supporter pattern 220 and the etching stopper film 202. For example, the upper electrode 280 may be formed on the outer sidewalls and inner sidewalls of the capacitor dielectric film 270 formed on the lower electrodes 260, and may be formed on the etching stopper film 202.

The upper electrode 280 may comprise, for example, at least one of doped polysilicon, a metal, a conductive metal nitride, and a metal silicide.

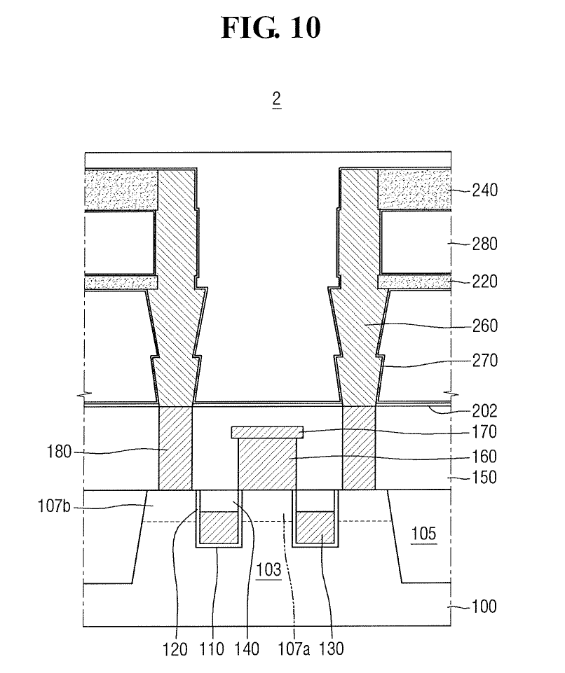

A semiconductor device according to an exemplary embodiment of the present inventive concept will hereinafter be described with reference to FIG. 10, focusing mainly on differences with the semiconductor device 1 of FIG. 9. Thus, elements or features that are substantially the same as elements or features previously discussed may be omitted or briefly discussed for convenience.

FIG. 10 is a cross-sectional view illustrating a semiconductor device 2 according to an exemplary embodiment of the present inventive concept.

Referring to FIG. 10, a semiconductor device 2, unlike the semiconductor device 1 of FIG. 9, structures may be formed as pillars that are completely filled with the lower electrode 260. For example, an upper electrode 280 is not formed in each of the structures.

Protrusions may be formed on the outer sidewalls of the lower electrodes 260. For example, stepwise protrusions may be formed on the outer sidewalls of the lower electrodes 260, but the present inventive concept is not limited thereto.

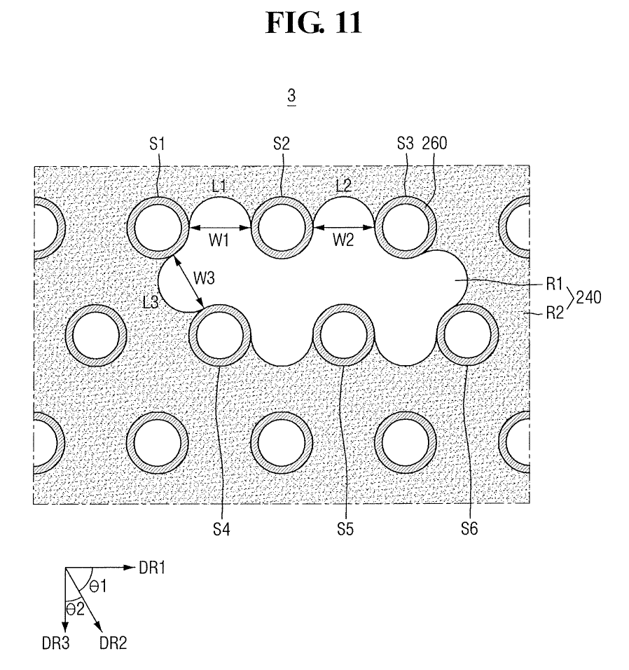

A semiconductor device 3 according to an exemplary embodiment of the present inventive concept will hereinafter be described with reference to FIG. 11, focusing mainly on differences with the semiconductor device 1 of FIG. 1. Thus, elements and features that are substantially the same as those described in FIG. 1 may be omitted or briefly discussed for convenience.

FIG. 11 is a schematic view illustrating a semiconductor device 3 according to an exemplary embodiment of the present inventive concept.

Referring to FIG. 11, a semiconductor device 3, unlike the semiconductor device 1 of FIG. 1, sidewalls of a second supporter pattern 240 between first and fourth structures S1 and S4 and between third and sixth structures S3 and S6 may have a convex shape toward a second region R2 of the second supporter pattern 240.

Accordingly, a third length L3 of the sidewall of the second supporter pattern 240 between the first and fourth structures S1 and S4 may be greater than a third distance W3 between the first and fourth structures S1 and S4.

In addition, the length of the sidewall of the second supporter pattern 240 between the third and sixth structures S3 and S6 may be greater than the distance between the third and sixth structures S3 and S6.

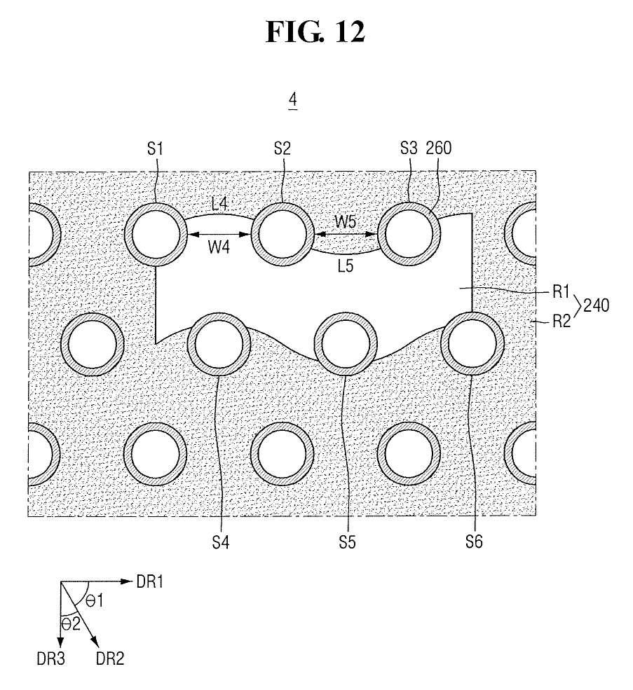

A semiconductor device 4 according to an exemplary embodiment of the present inventive concept will hereinafter be described with reference to FIG. 12, focusing mainly on differences with the semiconductor device 1 of FIG. 1. Thus, elements and features that are substantially the same as those described in FIG. 1 may be omitted or briefly discussed for convenience.

FIG. 12 is a schematic view illustrating a semiconductor device 4 according to an exemplary embodiment of the present inventive concept.

Referring to FIG. 12, in a semiconductor device 4, unlike in the semiconductor device 1 of FIG. 1, a sidewall of a second supporter pattern 240 between first and second structures S1 and S2 may have a convex shape toward the second region R2 of the second supporter pattern 240, and a sidewall of the second supporter pattern 240 between the second structure S2 and a third structure S3 may have a convex shape toward the first region R1 of the second supporter pattern 240. In other words, the first region R1 of the second supporter pattern 240 may have a wave like shape.

Accordingly, a fourth length L4 of the sidewall of the second supporter pattern 240 between the first and second structures S1 and S2 may be greater than a fourth distance W4 between the first and second structures S1 and S2. In addition, a fifth length L5 of the sidewall of the second supporter pattern 240 between the second and third structures S2 and S3 may be greater than a fifth distance W5 between the second and third structures S2 and S3.

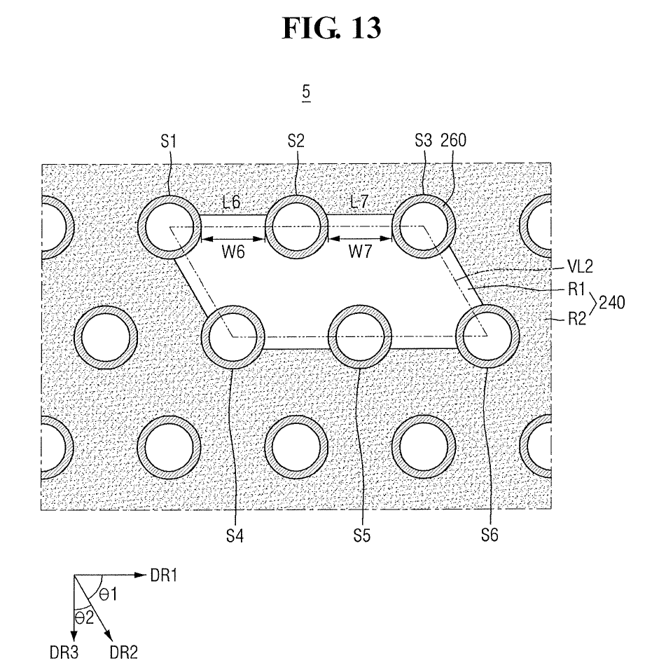

A semiconductor device 5 according to an exemplary embodiment of the present inventive concept will hereinafter be described with reference to FIG. 13, focusing mainly on differences with the semiconductor device 1 of FIG. 1. Thus, elements and features that are substantially the same as those described in FIG. 1 may be omitted or briefly discussed for convenience.

FIG. 13 is a schematic view illustrating a semiconductor device 5 according to an exemplary embodiment of the present inventive concept.

Referring to FIG. 13, in a semiconductor device 5, unlike in the semiconductor device 1 of FIG. 1, sidewalls of a second supporter pattern 240 between the first and second structures S1 and S2 and between the second structure S2 and a third structure S3 may extend in a first direction DR1.

For example, the sidewalls of the second supporter pattern 240, which are provided between the first through third structures S1 through S3 and fourth through sixth structures S4 through S6, may be parallel to second imaginary lines VL2 that sequentially connect the first through sixth structures S1 through S6.

Accordingly, a sixth length L6 of the sidewall of the second supporter pattern 240 between the first and second structures S1 and S2 may be greater than a sixth distance W6 between the first and second structures S1 and S2. In addition, a seventh length L7 of the sidewall of the second supporter pattern 240 between the second and third structures S2 and S3 may be greater than a seventh distance W7 between the second and third structures S2 and S3.

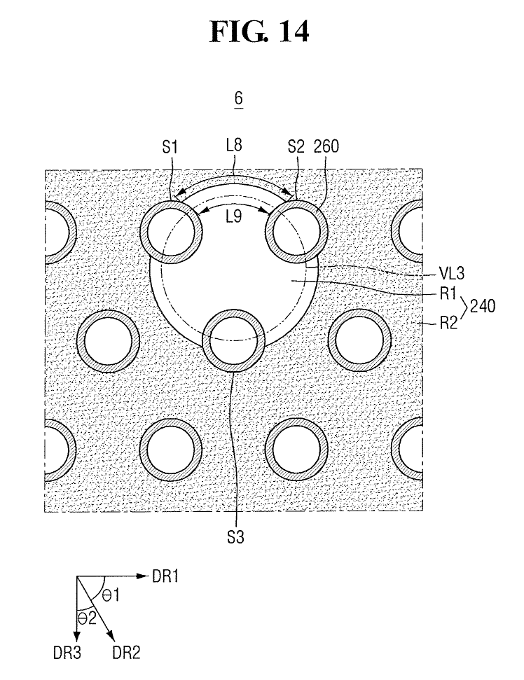

A semiconductor device 6 according to an exemplary embodiment of the present inventive concept will hereinafter be described with reference to FIG. 14, focusing mainly on differences with the semiconductor device 1 of FIG. 1. Thus, elements and features that are substantially the same as those described in FIG. 1 may be omitted or briefly discussed for convenience.

FIG. 14 is a schematic view illustrating a semiconductor device 6 according to an exemplary embodiment of the present inventive concept.

Referring to FIG. 14, a semiconductor device 6, unlike the semiconductor device 1 of FIG. 1, may include a second supporter pattern 240, and the second supporter pattern 240 may include a first region R1, which exposes parts of the sidewalls of a first structure S1, a second structure S2 spaced apart from the first structure S1 in a first direction DR1, and a third structure S3 spaced apart from the first structure S1 and the second structure S2 in a second direction DR2. A second region R2 of the second supporter pattern 240 may surround other parts of the sidewalls of the first through third structures S1 through S3.

The centers of the first through third structures S1 through S3 may be disposed along a third imaginary line VL3 that forms a circular shape. Sidewalls of the second supporter pattern 240 may form a circular shape having a larger diameter than a diameter of the circular shape formed by the third imaginary line VL3.

Accordingly, an eighth length L8 of a sidewall of the second supporter pattern 240 between the first and second structures S1 and S2 may be greater than a ninth length L9 of a part of the third imaginary line VL3 between the first and second structures S1 and S2.

In addition, the length of a sidewall of the second supporter pattern 240 between the second and third structures S2 and S3 may be greater than the length of a part of the third imaginary line VL3 between the second and third structures S2 and S3. Further, the length of a sidewall of the second supporter pattern 240 between the first and third structures S1 and S3 may be greater than the length of a part of the third imaginary line VL3 between the first and third structures S1 and S3.

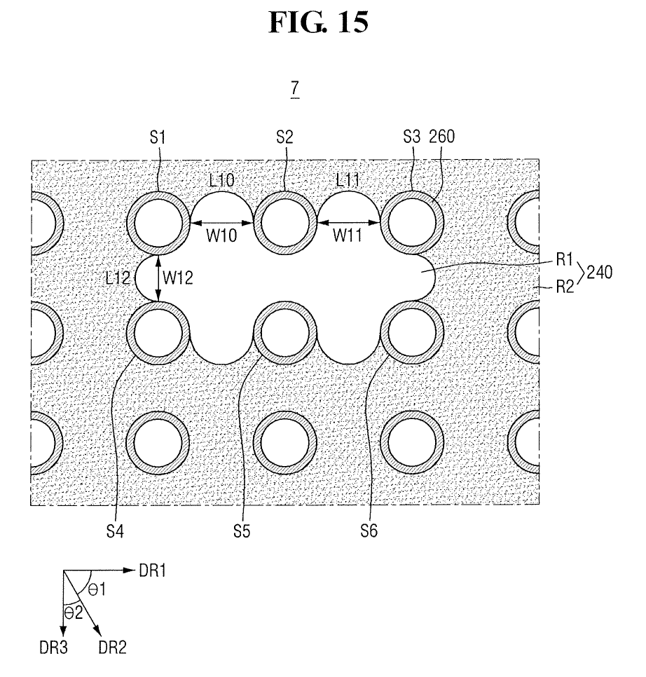

A semiconductor device 7 according to an exemplary embodiment of the present inventive concept will hereinafter be described with reference to FIG. 15, focusing mainly on differences with the semiconductor device 3 of FIG. 11. Thus, elements and features that are substantially the same as those described in FIG. 11 may be omitted or briefly discussed for convenience.

FIG. 15 is a schematic view illustrating the semiconductor device 7 according to an exemplary embodiment of the present inventive concept.

Referring to FIG. 15, in a semiconductor device 7, unlike in the semiconductor device 3 of FIG. 11, a fourth structure S4 may be spaced apart from a first structure S1 in a third direction DR3, a fifth structure S5 may be spaced apart from a second structure S2 in the third direction DR3, and a sixth structure S6 may be spaced apart from a third structure S3 in the third direction DR3.

In the semiconductor device 7, like in the semiconductor device 3 of FIG. 11, sidewalls of the second supporter pattern 240 between the first through sixth structures S1 through S6 may have a convex shape toward a second region R2 of the second supporter pattern 240.

Accordingly, a tenth length L10 of a sidewall of the second supporter pattern 240 between the first and second structures S1 and S2 may be greater than a tenth distance W10 between the first and second structures S1 and S2. An eleventh length L11 of a sidewall of the second supporter pattern 240 between the second and third structures S2 and S3 may be greater than an eleventh distance W11 between the second and third structures S2 and S3. A twelfth length L12 of a sidewall of the second supporter pattern 240 between the first and fourth structures S1 and S4 may be greater than a twelfth distance W12 between the first and fourth structures S1 and S4.

In an exemplary embodiment of the present inventive concept, the semiconductor device 7 may be symmetrical.

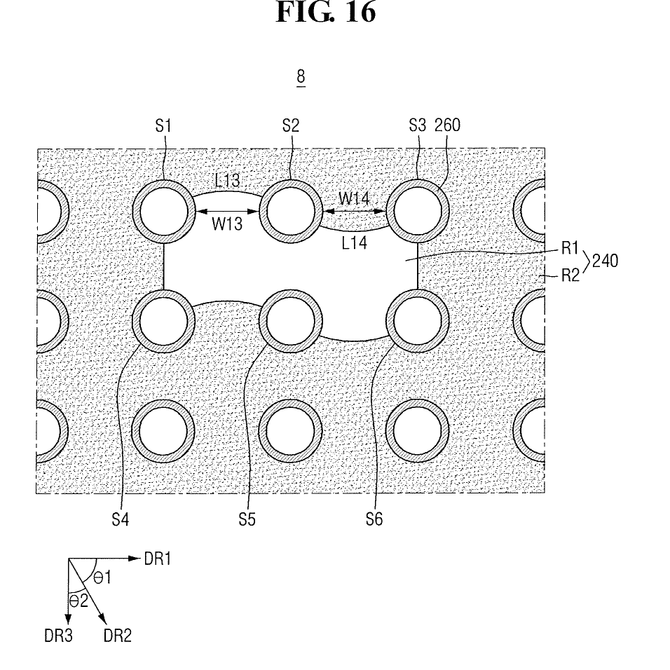

A semiconductor device 8 according to an exemplary embodiment of the present inventive concept will hereinafter be described with reference to FIG. 16, focusing mainly on differences with the semiconductor device 4 of FIG. 12. Thus, elements and features that are substantially the same as those described in FIG. 12 may be omitted or briefly discussed for convenience.

FIG. 16 is a schematic view illustrating a semiconductor device 8 according to an exemplary embodiment of the present inventive concept.

Referring to FIG. 16, in a semiconductor device 8, unlike in the semiconductor device 4 of FIG. 12, a fourth structure S4 may be spaced apart from a first structure S1 in a third direction DR3, a fifth structure S5 may be spaced apart from a second structure S2 in the third direction DR3, and a sixth structure S6 may be spaced apart from a third structure S3 in the third direction DR3. For example, the first structure S1 may be aligned with the fourth structure S4 in the third direction DR3, the second structure S2 may be aligned with the fifth structure S5 in the third direction DR3, and the third structure S3 may be aligned with the sixth structure S6 in the third direction DR3.

In the semiconductor device 8, like in the semiconductor device 4 of FIG. 12, a sidewall of the second supporter pattern 240 between the first and second structures S1 and S2 may have a convex shape toward a second region R2 of the second supporter pattern 240, and a sidewall of the second supporter pattern 240 between the second and third structures S2 and S3 may have a convex shape toward the second region R2 of the second supporter pattern 240. In other words, the first region R1 of the second supporter pattern 240 may have a wave like shape.

Accordingly, a thirteenth length L13 of the sidewall of the second supporter pattern 240 between the first and second structures S1 and S2 may be greater than a thirteenth distance W13 between the first and second structures S1 and S2. In addition, a fourteenth length L14 of the sidewall of the second supporter pattern 240 between the second and third structures S2 and S3 may be greater than a fourteenth distance W14 between the second and third structures S2 and S3.

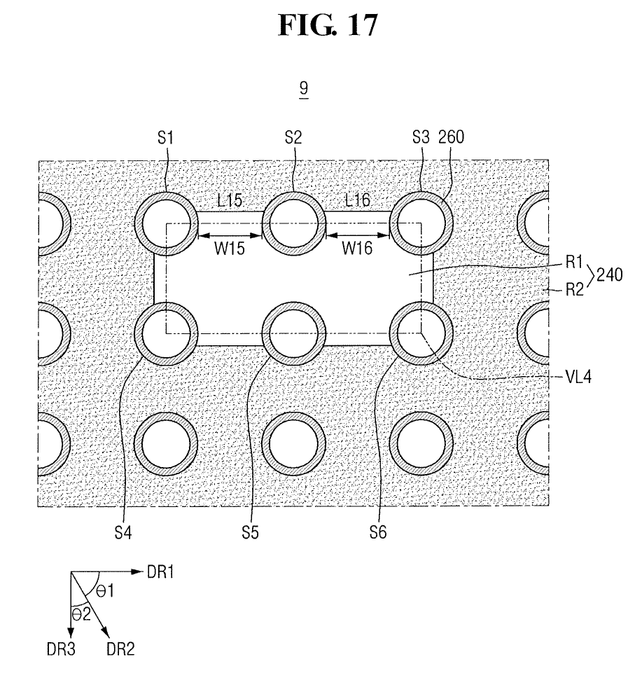

A semiconductor device 9 according to an exemplary embodiment of the present inventive concept will hereinafter be described with reference to FIG. 17, focusing mainly on differences with the semiconductor device 5 of FIG. 13. Thus, elements and features that are substantially the same as those described in FIG. 13 may be omitted or briefly discussed for convenience.

FIG. 17 is a schematic view illustrating a semiconductor device 9 according to an exemplary embodiment of the present inventive concept.

Referring to FIG. 17, in a semiconductor device 9, unlike in the semiconductor device 5 of FIG. 13, a fourth structure S4 may be spaced apart from a first structure S1 in a third direction DR3, a fifth structure S5 may be spaced apart from a second structure S2 in the third direction DR3, and a sixth structure S6 may be spaced apart from a third structure S3 in the third direction DR3. For example, the first through sixth structures S1 through S6 may be aligned with each other similar to that of the first through sixth structures S1 through S6 of FIG. 16.

In the semiconductor device 9, like in the semiconductor device 5 of FIG. 13, sidewalls of a second supporter pattern 240, which is provided between the first through sixth structures S1 through S6, may be parallel to fourth imaginary lines VL4 that sequentially connect the first through sixth structures S1 through S6. The fourth imaginary lines VL4 may form a rectangular shape.

Accordingly, a fifteenth length L15 of the sidewall of the second supporter pattern 240 between the first and second structures S1 and S2 may be greater than a fifteenth distance W15 between the first and second structures S1 and S2. In addition, a sixteenth length L16 of the sidewall of the second supporter pattern 240 between the second and third structures S2 and S3 may be greater than a sixteenth distance W16 between the second and third structures S2 and S3.

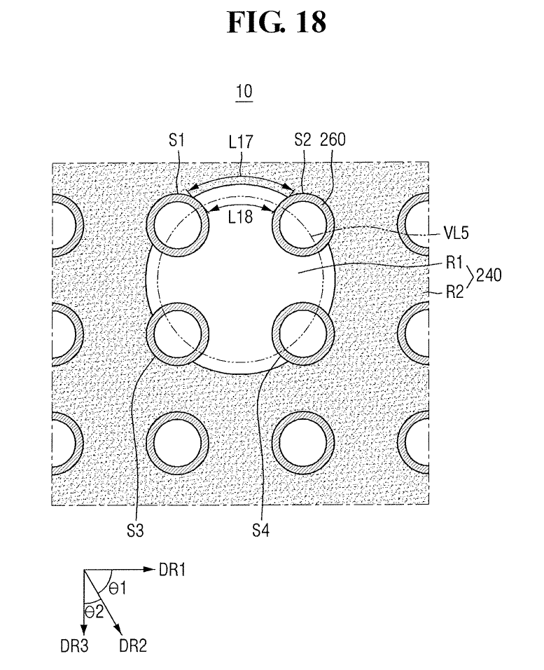

A semiconductor device 10 according to an exemplary embodiment of the present inventive concept will hereinafter be described with reference to FIG. 18, focusing mainly on differences with the semiconductor device 6 of FIG. 14. Thus, elements and features that are substantially the same as those described in FIG. 14 may be omitted or briefly discussed for convenience.

FIG. 18 is a schematic view illustrating a semiconductor device 10 according to an exemplary embodiment of the present inventive concept.

Referring to FIG. 18, in a semiconductor device 10, unlike in the semiconductor device 6 of FIG. 14, a first structure S1 may be spaced apart from a third structure S3 in a third direction DR3, and a second structure S2 may be spaced apart from a fourth structure S4 in the third direction DR3.

In the semiconductor device 10, like in the semiconductor device 6 of FIG. 14, the centers of first through fourth structures S1 through S4 may be disposed along a fifth imaginary line VL5 that forms a circular shape. Sidewalls of the second supporter pattern 240 may form a circular shape having a larger diameter than that of the circular shape formed by the fifth imaginary line VL5.

Accordingly, a seventeenth length L17 of the sidewall of the second supporter pattern 240 between the first and second structures S1 and S2 may be greater than an eighteenth length L18 of a part of the fifth imaginary line VL5 between the first and second structures S1 and S2.

According to the aforementioned and other exemplary embodiments of the present inventive concept, the length of sidewalls of a supporter pattern, which is formed between a plurality of structures including a plurality of lower electrodes, respectively, is formed to be greater than the distance between the structures. Thus, SBD margins can be secured among the lower electrodes. Thus, the integration density of a semiconductor device can be increased.

While the present inventive concept has been described with reference to exemplary embodiments thereof, it will be understood by those of ordinary skill in the art that various changes in form and details may be made thereto without departing from the spirit and scope of the present inventive concept as defined by the following claims.

What is claimed is:

1. A semiconductor device, comprising:
a substrate;
first, second and third structures disposed on the substrate and spaced apart from one another in a first direction, wherein each of the first, second and third structures includes lower electrodes; and
a supporter pattern supporting the first, second and third structures and including a first region and a second region, wherein the first region exposes first parts of sidewalls of the first, second and third structures, and the second region surrounds second parts of the sidewalls of the first, second and third structures,
wherein a first length of a sidewall of the supporter pattern between the first and second structures is greater than a first distance between the first and second structures, and
a second length of a sidewall of the supporter pattern between the second and third structures is greater than a second distance between the second and third structures.

2. The semiconductor device of claim 1, wherein the sidewalls of the supporter pattern between the first and second structures and between the second and third structures have a convex shape protruded toward the second region.

3. The semiconductor device of claim 1, wherein
the sidewall of the supporter pattern between the first and second structures has a convex shape protruded toward the second region, and
the sidewall of the supporter pattern between the second and third structures has a convex shape protruded toward the first region.

4. The semiconductor device of claim 1, wherein the sidewalls of the supporter pattern between the first and second structures and between the second and third structures extend in the first direction.

5. The semiconductor device of claim 1, further comprising:
fourth, fifth and sixth structures respectively spaced apart from the first, second and third structures, wherein the fourth, fifth and sixth structures are disposed in a second direction that forms an acute angle with the first direction,
wherein the first region of the supporter pattern exposes first parts of sidewalls of the fourth, fifth and sixth structures, and
the second region of the supporter pattern surrounds second parts of the sidewalls of the fourth, fifth and sixth structures.

6. The semiconductor device of claim 5, wherein lines sequentially connect centers of the first, second, third, fourth, fifth, and sixth structures have a parallelogrammatic shape.

7. The semiconductor device of claim 5, wherein a third length of a sidewall of the supporter pattern between the first and fourth structures is greater than a third distance between the first and fourth structures.

8. The semiconductor device of claim 1, further comprising:
fourth, fifth and sixth structures respectively spaced apart from the first, second and third structures, wherein the fourth, fifth and sixth structures are disposed in a third direction that is perpendicular to the first direction,
wherein the first region of the supporter pattern exposes first parts of sidewalls of the fourth, fifth and sixth structures, and
the second region of the supporter pattern surrounds second parts of the sidewalls of the fourth, fifth and sixth structures.

9. The semiconductor device of claim 8, wherein lines sequentially connect centers of the first, second, third, fourth, fifth and sixth structures have a rectangular shape.

10. The semiconductor device of claim 8, wherein a fourth length of a sidewall of the supporter pattern between the first and fourth structures is greater than a fourth distance between the first and fourth structures.

11. The semiconductor device of claim 1, further comprising:
a capacitor dielectric film disposed on the lower electrodes; and
an upper electrode disposed on the capacitor dielectric film.

12. A semiconductor device, comprising:
a substrate;
a first structure disposed on the substrate and including a first lower electrode;
a second structure disposed on the substrate and including a second lower electrode, wherein the second structure is spaced apart from the first structure in a first direction;
a third structure disposed on the substrate and including a third lower electrode, wherein the third structure is spaced apart from the first structure in a second direction that crosses the first direction; and
a supporter pattern supporting the first, second and third structures and including a first region and a second region, wherein the first region exposes first parts of sidewalls of the first, second and third structures, and the second region surrounds second parts of the sidewalls of the first, second and third structures,
wherein a center of each of the first, second and third structures is a point on a circle that intersects each of the first, second and third structures, and
a first length of a sidewall of the supporter pattern between the first and second structures is greater than a second length of a part of the circle between the first and second structures.

13. The semiconductor device of claim 12, wherein an angle that the first and second directions form with each other is about 90 degrees.

14. The semiconductor device of claim 12, wherein an angle that the first and second directions form with each other is an acute angle.

15. The semiconductor device of claim 12, wherein the first through third structures have at least one of a cylindrical shape or a pillar shape.

16. A semiconductor device, comprising:
a substrate;
first, second and third structures disposed on the substrate and spaced apart from one another in a first direction, wherein each of the first, second and third structures includes lower electrodes;
fourth, fifth and sixth structures respectively spaced apart from the first, second and third structures in a second direction crossing the first direction, wherein each of the fourth, fifth and sixth structures includes lower electrodes; and
a supporter pattern supporting the first, second, third, fourth, fifth and sixth structures and including a first region and a second region, wherein the first region exposes first parts of sidewalls of the first, second, third, fourth, fifth and sixth structures, and the second region surrounds second parts of the sidewalls of the first, second, third, fourth, fifth and sixth structures,
wherein a first length of a sidewall of the supporter pattern between the first and second structures is greater than a first distance between the first and second structures, and
wherein a second length of a sidewall of the supporter pattern between the first and fourth structures is greater than a second distance between the first and fourth structures.

17. The semiconductor device of claim 16, wherein the sidewalls of the supporter pattern between the first and second structures and between the first and fourth structures have an arch shape.

18. The semiconductor device of claim 16, wherein an angle that the first and second directions form with each other is an acute angle.

19. The semiconductor device of claim 16, wherein the first, second and third structures are respectively aligned with the fourth, fifth and sixth structures.

20. The semiconductor device of claim 16, wherein a capacitor dielectric film is disposed on the lower electrodes of the first, second, third, fourth, fifth and sixth structures.
